(19) United States
(12) Patent Application Publication
(10) Pub. No.: US 2025/0171249 A1
(43) Pub. Date: May 29, 2025

(54) SUBSTRATE TRANSPORT APPARATUS, SUBSTRATE PROCESSING APPARATUS, AND INSPECTION METHOD

(71) Applicant: SCREEN Holdings Co., Ltd., Kyoto (JP)

(72) Inventors: Takuya SATO, Kyoto (JP); Yuichi TAKAYAMA, Kyoto (JP); Hiroyuki KAWAHARA, Kyoto (JP)

(21) Appl. No.: 18/957,654

(22) Filed: Nov. 22, 2024

(30) Foreign Application Priority Data
Nov. 29, 2023 (JP) 2023-202087

(51) Int. Cl. B65G 47/90

(52) U.S. Cl. CPC B65G 47/905

(57) ABSTRACT

A taking hand including a first guide member provided on an upper surface of a base member and with which a peripheral edge of a substrate comes into contact, a first sensor configured to sense the substrate coming into contact with the first guide member, a second guide member provided on the upper surface of the base member and with which the peripheral edge of the substrate comes into contact, and a second sensor configured to sense the substrate coming into contact with the second guide member; and a comparison unit configured to determine an inclination state of the taking hand with respect to the substrate based on a difference between a timing at which the first sensor senses the substrate and a timing at which the second sensor senses the substrate are provided.

This application claims priority to Japanese Patent Application No. 2023-202087 filed Nov. 29, 2023, the subject matter of which is incorporated herein by reference in entirety.

### BACKGROUND OF THE INVENTION

The present invention relates to a substrate transport apparatus that transfers various substrates such as a semiconductor substrate, a substrate for flat panel display (FPD), such as liquid crystal display and organic electroluminescence (EL) display, a glass substrate for a photomask, and an optical disk substrate, and a substrate processing apparatus including the substrate transport apparatus.

### DESCRIPTION OF THE RELATED ART

Conventionally, as a substrate transport apparatus realizing substrate transport required for substrate processing, there is a substrate transport apparatus having a hand main body having a plurality of tactile sensors. When the substrate is placed on the plurality of tactile sensors, the tactile sensors detect the force in the Z-axis direction. In this way, it is possible to recognize that the substrate is normally placed on the hand main body. It is also possible to detect the angular deviation of the hand main body in the Z-axis direction by the tactile sensors.

However, a conventional substrate transport apparatus including a tactile sensor is not configured to fully utilize the tactile sensor. For example, according to the configuration of JP 2022-91240 A, abnormality in substrate transport is merely detected by using a tactile sensor.

At present, there is a demand for a substrate transport apparatus that facilitates maintenance. In order to facilitate the maintenance, it is sufficient to automatically perceive the time required for the maintenance. It is considered that the tactile sensor can detect a deviation in the positional relationship between the substrate and the hand main body, but a specific configuration for realizing this has not yet been studied.

### SUMMARY OF THE INVENTION

The present invention has been made in view of such circumstances, and an object thereof is to provide a substrate transport apparatus and a substrate processing apparatus that automatically perceive a time required for maintenance and facilitate maintenance. Another object of the present invention is to provide an inspection method for inspecting a required time for maintenance of a substrate transport apparatus.

In order to solve the above problems, the present invention has the following configurations.

That is, the present invention is a substrate transport apparatus having a hand capable of transporting a substrate in a horizontal posture, in which
the hand includes
a base member,
a plurality of guides provided on an upper surface of the base member and with which a peripheral edge of a substrate comes into contact, and
a plurality of sensors configured to individually sense the substrate coming into contact with each of the guides, and
the substrate transport apparatus includes a determination unit configured to determine an inclination state of the hand with respect to the substrate based on a time difference between timings at which each of the sensors individually senses the substrate.

### Operation and Effect

According to the above configuration, a hand including a plurality of guides provided on an upper surface of the base member and with which a peripheral edge of a substrate comes into contact, and a plurality of sensors individually sensing the substrate coming into contact with each of the guides; and a determination unit determining an inclination state of the hand with respect to the substrate based on a time difference between timings at which each of the sensors individually senses the substrate are provided. With such a configuration, it is possible to provide a substrate transport apparatus capable of continuously detecting a temporal change of the hand. There is a predetermined relationship between a timing at which one sensor senses the substrate and a timing at which the other sensor senses the substrate. When the predetermined relationship collapses while the timing is measured for each of the substrates held by the hand, it can be determined that the positional deviation of the hand with respect to the substrate has occurred. Therefore, according to the present invention, it is possible to provide a substrate transport apparatus that automatically perceives a time required for maintenance and facilitates maintenance.

In the substrate transport apparatus, it is preferable that the hand includes
a first guide provided at a distal end portion of the base member among the guides,
a second guide provided at a proximal end portion of the base member among the guides,
a first sensor configured to sense the substrate coming into contact with the first guide among the sensors, and
a second sensor configured to sense the substrate coming into contact with the second guide among the sensors, and
in a case where a direction connecting the proximal end portion of the base member and the distal end portion of the base member is designated as a front-rear direction,
the determination unit is configured to determine an inclination state of the hand in the front-rear direction based on a time difference between a timing at which the first sensor senses the substrate and a timing at which the second sensor senses the substrate.

### Operation and Effect

According to the above configuration, the first guide is provided at the distal end portion of the base member, and the second guide is provided at the proximal end portion of the base member. The first guide includes the first sensor sensing a substrate, and the second guide includes the second sensor sensing a substrate. The determination unit determines an inclination state of the hand in the front-rear direction based on a time difference between a timing at which the first sensor senses the substrate and a timing at which the second sensor senses the substrate. When the substrate transport apparatus is operated, a temporal change of the hand in which the inclination state of the distal end portion changes with respect to the proximal end portion may occur. According to the above configuration, since the first guide is provided at the distal end portion of the base member and the second guide is provided at the proximal end portion of the base member, such a temporal change can be easily sensed.

In the substrate transport apparatus, it is preferable that the hand includes,
in a case where a direction connecting a proximal end portion of the base member and a distal end portion of the base member is designated as a front-rear direction, and a direction orthogonal to the front-rear direction in a horizontal plane is designated as a right-left direction,
a first guide provided on one end side in the right-left direction of the distal end portion of the base member among the guides,
a second guide provided on the other end side in the right-left direction of the distal end portion of the base member among the guides,
a first sensor configured to sense the substrate coming into contact with the first guide among the sensors, and
a second sensor configured to sense the substrate coming into contact with the second guide among the sensors, and
the determination unit is configured to determine an inclination state of the hand in the right-left direction based on a time difference between a timing at which the first sensor senses the substrate and a timing at which the second sensor senses the substrate.

### Operation and Effect

According to the above configuration, the first guide is provided on one end side in the right-left direction of the distal end portion of the base member, the second guide is provided on the other end side in the right-left direction of the distal end portion of the base member, and the determination unit determines an inclination state of the hand in the right-left direction based on a time difference between a timing at which the first sensor senses the substrate and a timing at which the second sensor senses the substrate. When the substrate transport apparatus is operated, a temporal change of the hand in which one of the distal end portions is displaced downward with respect to the other of the distal end portions may occur. According to the above configuration, since the first guide is provided at one end of the distal end portion of the base member, and the second guide is provided at the other end of the distal end portion of the base member, such a temporal change can be easily sensed.

In the substrate transport apparatus, it is preferable that the hand includes
at least one third guide provided at the proximal end portion of the base member and with which the peripheral edge of the substrate comes into contact among the guides, and
a third sensor configured to sense the substrate coming into contact with the third guide among the sensors, and
the determination unit is configured
   to determine an inclination state of the hand in the front-rear direction based on a time difference between a timing at which the first sensor senses the substrate and a timing at which the third sensor senses the substrate, and
   to determine an inclination state of the hand in the right-left direction based on a time difference between a timing at which the first sensor senses the substrate and a timing at which the second sensor senses the substrate.

### Operation and Effect

According to the above configuration, the hand includes a third guide provided at the proximal end portion of the base member and with which the peripheral edge of the substrate comes into contact, and a third sensor sensing a substrate coming into contact with the third guide. The determination unit determines an inclination state of the hand in the front-rear direction based on a time difference between a timing at which the first sensor senses the substrate and a timing at which the third sensor senses the substrate. The determination unit determines an inclination state of the hand in the right-left direction based on a time difference between a timing at which the first sensor senses the substrate and a timing at which the second sensor senses the substrate. With such a configuration, it is possible to detect the inclination due to the temporal change of the hand in two directions orthogonal to each other, so that maintenance of the substrate transport apparatus is facilitated.

It is preferable that the substrate transport apparatus further includes a notification unit configured to notify that an index value indicating the time difference is larger than a predetermined value.

### Operation and Effect

According to the above configuration, the notification unit notifies that the index value indicating the time difference in substrate detection timing by the sensor is larger than the predetermined value. This facilitates maintenance of the substrate transport apparatus.

It is preferable that the substrate transport apparatus further includes
an elevation mechanism configured to vertically move the hand; and
an elevation control unit configured to control the elevation mechanism,
in which the elevation control unit is configured to move the hand located at a lower portion of the substrate in a stationary state upward to bring the substrate into contact with the plurality of guides.

### Operation and Effect

According to the above configuration, the elevation mechanism vertically moving the hand and the elevation control unit controlling the elevation mechanism are provided. The elevation control unit causes the hand located at a lower portion of the substrate in a stationary state to move upward to bring the substrate into contact with the plurality of guides. With such a configuration, the substrate can be brought into contact with the plurality of guides at the same time. Therefore, according to the above configuration, the object of the present invention can be more easily realized.

In the substrate transport apparatus, it is preferable that the determination unit is configured to determine an inclination state of the hand with respect to the substrate based on a time difference between two timings most separated with time among respective timings at which each of the sensors individually senses the substrate.

### Operation and Effect

According to the above configuration, an inclination state of the hand with respect to the substrate is determined based on a time difference between two timings most separated with time among respective timings at which each of the sensors individually senses the substrate. With such a configuration, the temporal change of the hand can be more sensitively sensed. Therefore, according to the above configuration, the object of the present invention can be more easily realized.

In the substrate transport apparatus, it is preferable that each of the sensors is a tactile sensor and is provided between the base member and each of the guides.

### Operation and Effect

According to the above configuration, each of the sensors is a tactile sensor and is provided between the base member and each of the guides. With such a configuration, each tactile sensor can more directly and reliably detect the substrate placed on the base member.

In the substrate transport apparatus, it is preferable that each of the guides includes a support portion bringing a lower portion of the substrate into contact with each of the guides, and a wall portion bringing an outer peripheral surface of the substrate into contact with each of the guides.

### Operation and Effect

According to the above configuration, each of the guides includes a support portion bringing a lower portion of the substrate into contact with each of the guides, and a wall portion bringing an outer peripheral surface of the substrate into contact with each of the guides. With such a configuration, a contact portion between the substrate and the guide is reduced as much as possible when the substrate is gripped. When the outer peripheral surface of the substrate comes into contact with the wall portion, positional displacement of the substrate caused when the substrate is gripped is appropriately prohibited. Therefore, according to the above configuration, it is possible to provide a substrate transport apparatus suitable for transporting a substrate.

In the substrate transport apparatus, it is preferable that the base member includes a plurality of recesses in which each of the sensors is embedded.

### Operation and Effect

According to the above configuration, the base member includes the plurality of recesses in which each of the sensors is embedded. With such a configuration, the thickness of the hand in the height direction can be suppressed, so that it is possible to provide a substrate transport apparatus in which the hand does not collide with the substrate during substrate transport.

In the substrate transport apparatus, it is preferable that each of the sensors is configured to sense whether or not the substrate comes into contact with each corresponding guide.

### Operation and Effect

According to the above configuration, each of the sensors senses whether or not the substrate comes into contact with each corresponding guide. With such a configuration, the present invention can be realized by a relatively inexpensive sensor.

In a substrate processing apparatus including the above-described substrate transport apparatus, it is preferable that the substrate processing apparatus includes a carrier placement shelf capable of placing a carrier on which substrates in a horizontal posture are stacked in a vertical direction and stored on the carrier placement shelf,
in which loading and unloading of the substrate into and from the carrier are performed by the substrate transport apparatus.

### Operation and Effect

According to the above configuration, a carrier placement shelf capable of placing a carrier on which substrates in a horizontal posture are stacked in a vertical direction and stored thereon is provided. Therefore, according to the above configuration, the temporal change of the hand can be detected with reference to the carrier.

In the substrate processing apparatus, it is preferable that the determination unit is configured to determine an inclination state of the carrier with respect to the hand based on a time difference between timings at which each of the sensors individually senses the substrate.

### Operation and Effect

According to the above configuration, in a case where the substrate transported by the hand is stored in the carrier, the determination unit determines an inclination state of the carrier with respect to the hand based on a time difference between timings at which each of the sensors individually senses the substrate. Therefore, according to the above configuration, it is possible to know whether the carrier can maintain the horizontal state.

It is preferable that the substrate processing apparatus including the above-described substrate transport apparatus further includes a single-substrate-type processing unit configured to process substrates transported by the substrate transport apparatus one by one.

### Operation and Effect

According to the above configuration, a single-substrate-type processing unit performing predetermined processing on substrates transported by the substrate transport apparatus one by one is provided. According to the above configuration, it is possible to provide a substrate processing apparatus that facilitates maintenance and can perform desired substrate processing.

The present specification also discloses the following invention.

An inspection method for a substrate transport apparatus having a hand including a base member, a plurality of guides provided on an upper surface of the base member and with which a peripheral edge of a substrate comes into contact respectively, and a plurality of sensors configured to individually sense the substrate coming into contact with each of the guides, the inspection method including:
causing the hand to acquire the substrate; and
determining an inclination state of the hand with respect to the substrate based on a time difference between timings at which each of the sensors individually senses the substrate.

### Operation and Effect

According to the above configuration, an acquisition process of causing the hand to acquire the substrate, and a determination process of determining an inclination state of the hand with respect to the substrate based on a time difference between timings at which each of the sensors individually senses the substrate are provided. With such a configuration, it is possible to provide an inspection method capable of reliably inspecting a temporal change of a hand.

As described above, according to the present invention, it is possible to provide a substrate transport apparatus and a substrate processing apparatus that automatically perceive a time required for maintenance and facilitate maintenance. According to the present invention, it is possible to provide an inspection method for inspecting a required time for maintenance of a substrate transport apparatus.

### BRIEF OF DESCRIPTION OF THE DRAWINGS

FIG. 1 is a plan view illustrating an overall configuration of a substrate processing apparatus of an embodiment;

FIG. 2 is a side view illustrating a carrier of an embodiment;

FIG. 3 is a left side view illustrating configurations of a taking hand and a returning hand of an embodiment;

FIG. 4 is a plan view illustrating the configurations of the taking hand and the returning hand of an embodiment;

FIG. 5 is a plan view illustrating an operation of the taking hand of an embodiment;

FIG. 6 is a cross-sectional view illustrating an operation of the taking hand of an embodiment;

FIG. 7 is an exploded perspective view illustrating the configuration of the taking hand of an embodiment;

FIG. 8 is an exploded perspective view illustrating the configuration of the taking hand of an embodiment;

FIG. 9 is a schematic view illustrating an inspection method for the taking hand of an embodiment;

FIG. 10 is a schematic view illustrating the inspection method for the taking hand of an embodiment;

FIG. 11 is a schematic view illustrating the inspection method for the taking hand of an embodiment;

FIG. 12 is a schematic view illustrating the inspection method for the taking hand of an embodiment;

FIG. 13 is a schematic view illustrating the inspection method for the taking hand of an embodiment;

FIG. 14 is a schematic view illustrating the inspection method for the taking hand of an embodiment;

FIG. 15 is a flowchart illustrating the inspection method for the taking hand of an embodiment;

FIGS. 16A to 16C are schematic views illustrating a first modification of the present invention;

FIG. 17 is a plan view illustrating the first modification of the present invention; and

FIG. 18 is a cross-sectional view illustrating the first modification of the present invention.

### DESCRIPTION OF THE PREFERRED EMBODIMENTS

Hereinafter, embodiments of the present invention will be described with reference to the drawings. The following embodiment is a substrate processing apparatus on which a substrate transport apparatus of the present invention is mounted. The substrate transport apparatus of the present invention corresponds to an indexer block in the substrate processing apparatus of an embodiment. The indexer block has an indexer robot including a hand that transports a substrate.

### EMBODIMENT

### 1. Overall Configuration

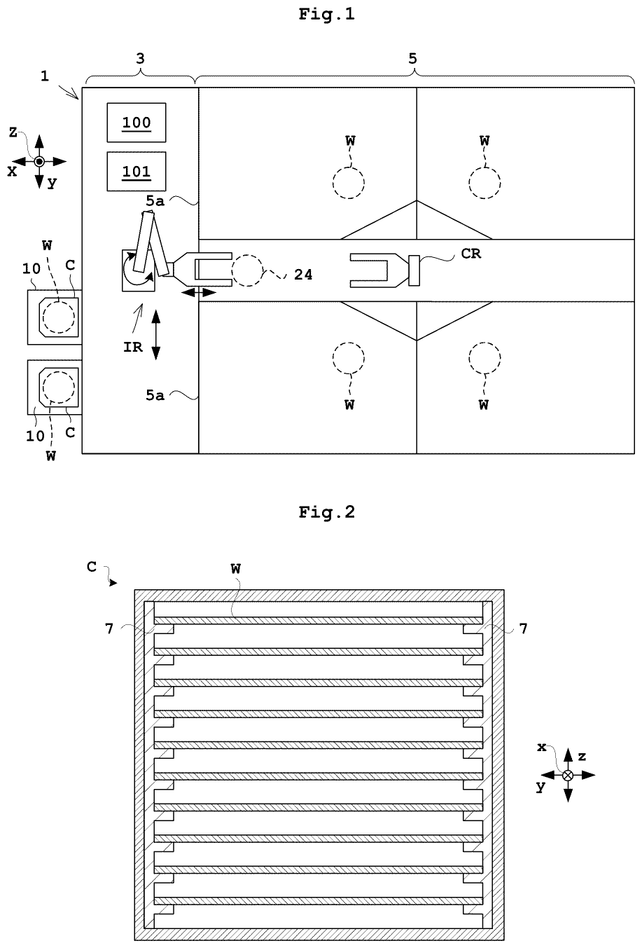

As illustrated in FIG. 1, a substrate processing apparatus 1 of this example includes a load port 10, an indexer block 3, and a processing block 5. The substrate processing apparatus 1 of this example relates to single-substrate-type processing, and is configured to acquire substrates W in a horizontal posture one by one from a carrier C, perform the substrate processing, and return the substrates W one by one to the carrier.

In the present specification, for convenience, a direction in which the indexer block 3 and the processing block 5 in the substrate processing apparatus 1 are arranged is referred to as a “front-rear direction X”. The front-rear direction X extends horizontally. Of the front-rear direction X, a direction from the processing block 5 toward the indexer block 3 in the substrate processing apparatus 1 is referred to as “front”. A direction opposite to the front is referred to as “rear”. A direction extending horizontally orthogonal to the front-rear direction X is referred to as a “width direction Y”. One direction of the “width direction Y” is referred to as a “right side” for convenience, and the other direction is referred to as a “left side” for convenience. A direction (height direction) orthogonal to the front-rear direction X and the width direction Y is referred to as a “vertical direction Z” for convenience. In each drawing, front, rear, right, left, top, and bottom are appropriately shown for reference.

The load port 10 corresponds to a carrier placement shelf of the present invention. The load port 10 is a carrier placement shelf on which the carrier C is placed. A plurality of load ports 10 are arranged in the width direction Y, and each one of the carriers C can be placed. The load port 10 can place the carrier C in which substrates in a horizontal posture are stacked in the vertical direction and stored.

That is, the carrier C stores a plurality of substrates W in the vertical direction Z at predetermined intervals in a horizontal posture. The carrier C is provided with an opening for taking out and storing a substrate on one side surface. A plurality of (for example, 25) substrates W are stacked and stored in one carrier C at regular intervals in a horizontal posture. FIG. 2 is a cross-sectional view illustrating the configuration of the carrier C. In the carrier C, a comb-shaped member 7 having a plurality of protrusions for placing the substrate W is provided at both ends of a carrier housing. The protrusion of the comb-shaped member 7 is configured to place the end portion of the substrate W. The protrusion extends in the front-rear direction X. The protrusions are arranged at intervals of 1 cm. Examples of the carrier C include a sealed front opening unify pod (FOUP). In the present invention, an open type container may be employed as the carrier C.

The indexer block 3 corresponds to the substrate transport apparatus of the present invention. The indexer block 3 has a rectangular shape extending in the width direction Y The indexer block 3 is provided with an indexer robot IR having a taking hand 11a and a returning hand 11b capable of transporting a substrate in a horizontal posture. The indexer robot IR is horizontally movable in the width direction Y. The indexer robot IR has a hand capable of holding and transporting the substrate W. The hand is supported by an articulated arm configured to be capable of turning, lifting, and advancing and retracting. The indexer robot IR can access the carrier C on the load port 10 and a path 24 provided in front of the processing block 5. The indexer robot IR can perform two operations including an operation of acquiring the substrates W in a horizontal posture one by one from the carrier C and placing the substrates W in the path 24, and an operation of acquiring the substrates W in the horizontal posture placed in the path 24 one by one and returning the substrates W to the carrier C. The non-processed substrate W held by the carrier C is transported to the path 24 by the indexer robot IR. The processed substrate W is placed on the path 24 and returned to the carrier C by the indexer robot IR. The indexer block 3 is configured to perform loading and unloading of the substrate W into and from the carrier C.

The processing block 5 is configured to perform predetermined processing on the substrate W. In the processing block 5, a plurality of single-substrate-type processing chambers 5a are arranged. The single-substrate-type processing chamber 5a corresponds to the single-substrate-type processing unit of the present invention. The single-substrate-type processing chamber 5a is configured to process the substrates W transported by the indexer block 3 one by one.

The arrangement of the single-substrate-type processing chambers 5a in the processing block 5 will be described. That is, in the processing block 5 of the present invention, three single-substrate-type processing chambers 5a are arranged in a middle layer region, an upper layer region, and a lower layer region, respectively, to form a laminate. Two laminates are arranged back and forth on the right side of the processing block 5. Similarly, two laminates are arranged back and forth on the left side of the processing block 5. Therefore, twelve single-substrate-type processing chambers 5a are mounted on the processing block 5.

A substrate transfer region extending in the front-rear direction X is provided in a central portion of the processing block 5. A center robot CR reciprocate in the substrate transfer region, and can acquire the substrates W in a horizontal posture from the path 24 one by one and transfer the substrates W to any one of the single-substrate-type processing chambers 5a. The center robot CR can acquire the substrates W in a horizontal posture held by the single-substrate-type processing chambers 5a one by one and return the substrates W to the path 24. As described above, the center robot CR can access each of the single-substrate-type processing chambers 5a and the path 24.

Examples of the substrate processing performed by the single-substrate-type processing chamber 5a include substrate cleaning processing. The substrate processing apparatus 1 of this example may be configured to perform various kinds of substrate processing using a chemical liquid in addition to the substrate cleaning processing.

### 2. Configuration of Indexer Robot

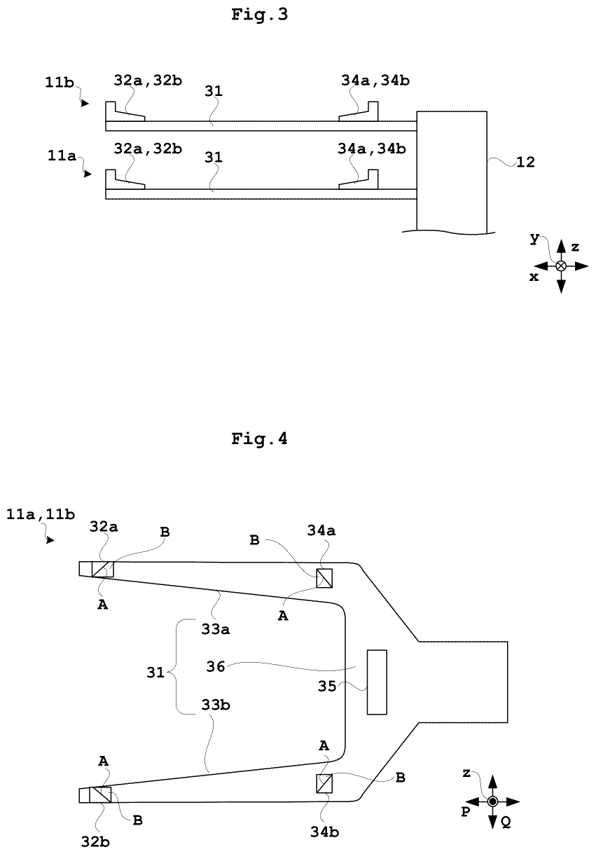

FIG. 3 schematically illustrates a distal end portion related to substrate holding in the indexer robot TR. The indexer robot IR includes the taking hand 11a and the returning hand 11b. The returning hand 11b and the taking hand 11a are held by an arm 12 in a stacked state in the vertical direction Z. The arm 12 can individually advance and retreat the returning hand 11b and the taking hand 11a in the front-rear direction X. In the configuration of FIG. 3, the returning hand 11b and the taking hand 11a are arranged in this order from the top to the bottom, but the arrangement order of the members can be appropriately changed.

The taking hand 11a corresponds to the hand of the present invention. The taking hand 11a enters between the substrates W vertically adjacent to each other so as to hold the non-processed substrates W from the carrier C one by one and transport the substrates W to the path 24.

The taking hand 11a has a base member 31 that is flat in a horizontal plane, a guide member 32a, and a guide member 34a. The base member 31 has a shape so as to be able to enter between the substrates. A direction connecting a proximal end portion and a distal end portion of the base member 31 is referred to as a front-rear direction P (see FIG. 4). A direction orthogonal to the front-rear direction in a horizontal plane is referred to as a right-left direction Q (see FIG. 4). The guide member 32a corresponds to the first guide of the present invention. The guide member 34a corresponds to the second guide of the present invention.

The guide member 32a and the guide member 32b are at the distal end portion of the taking hand 11a and are configured to bring the end portion of the substrate W into contact therewith. That is, the guide member 32a is a tab provided at the distal end portion of the base member 31 and is a member in contact with the substrate W. On the other hand, the guide member 34a is a tab provided at the proximal end portion of the base member 31 and is a member in contact with the substrate W. The guide member 32a and the guide member 34a are provided on the upper surface of the base member 31. Thus, the guide member 32a and the guide member 34a are configured to hold the upper substrate W from below.

The guide member 32a is provided on one end side in the right-left direction Q of the distal end portion of the base member 31. On the other hand, guide member 32b is provided on the other end side in the right-left direction Q of the distal end portion of the base member 31.

The guide member 32a and the guide member 34a each have a thick portion and a thin portion. Therefore, the guide member 32a and the guide member 34a are partially different in thickness in the height direction. The end portion (bevel portion) of the substrate W can come into contact with the wall portion facing the proximal end portion of the taking hand 11a in the thick portion of the guide member 32a. On the other hand, the end portion (bevel portion) of the substrate W can come into contact with the wall portion facing the distal end portion of the taking hand 11a in the thick portion of the guide member 34a.

The peripheral edge portion of the lower surface of the substrate can come into contact with an upward-facing flat portion in the thin portion of each of the guide member 32a and the guide member 34a. The guide member 32a and the guide member 34a correspond to the plurality of guides of the present invention. The guide member 32a and the guide member 34a are provided on the upper surface of the base member 31, and the peripheral edge of the substrate is configured to come into contact therewith.

Since the guide member 32a and the guide member 32b provided at the distal end portion of the base member 31 are tapered, this point will be described. The upper surface of the thin portion of each of the guide member 32a and the guide member 32b is inclined as illustrated in FIG. 3. That is, the thin portion is configured such that the thickness in the height direction decreases as it goes away from the thick portion. As described above, the guide member 32a and the guide member 32b each include a support portion (tapered portion: thin portion) that brings the lower portion of the substrate W into contact therewith, and a wall portion (side surface of the thick portion) that brings the outer peripheral surface of the substrate into contact therewith.

Similarly, a guide member 34a and a guide member 34b provided at the proximal end portion of the base member 31 are tapered as illustrated in FIG. 3. That is, the thin portion is configured such that the thickness in the height direction decreases as it goes away from the thick portion. As described above, the guide member 34a and the guide member 34b each include a support portion (tapered portion: thin portion) that brings the lower portion of the substrate W into contact therewith, and a wall portion (side surface of the thick portion) that brings the outer peripheral surface of the substrate into contact therewith.

The returning hand 11b has the same configuration as the taking hand 11a described above. That is, the returning hand 11b has the base member 31, the guide member 32a, and the guide member 32b. In the returning hand 11b, the configuration in which the guide member 32a and the guide member 32b are provided at the distal end portion of the base member 31 and the configuration in which the guide member 32a and the guide member 32b each have a thick portion and a thin portion are the same as the configuration of the taking hand 11a. The returning hand 11b of this example is provided to transport the clean substrate W having been subjected to cleaning processing. By selectively using the hand in the forward path and the backward path in the reciprocating operation of the substrate W, it is not necessary to hold the substrate W after the cleaning processing by the hand holding the substrate W before the cleaning processing. Therefore, the cleanliness of the substrate W having been subjected to cleaning processing is maintained by providing the returning hand 11b.

The returning hand 11b does not necessarily need a first sensor 22a, a sensor 22b, a sensor 26a, and a sensor 26b to be described later.

FIG. 4 is a plan view illustrating the taking hand 11a and the returning hand 11b. The taking hand 11a and the returning hand 11b each include a connecting portion 36, and a first blade 33a and a second blade 33b branched from the connecting portion 36. The connecting portion 36 is configured to connect the first blade 33a and the second blade 33b. The first blade 33a is a member extending in the front-rear direction P to hold one end portion of the substrate W, and the second blade 33b is a member extending in the front-rear direction P to hold the other end portion of the substrate W.

The guide member 32a is disposed on the first blade 33a. The guide member 32b is disposed on the second blade 33b. The guide member 34a is disposed on the first blade 33a. The guide member 34b is disposed on the second blade 33b.

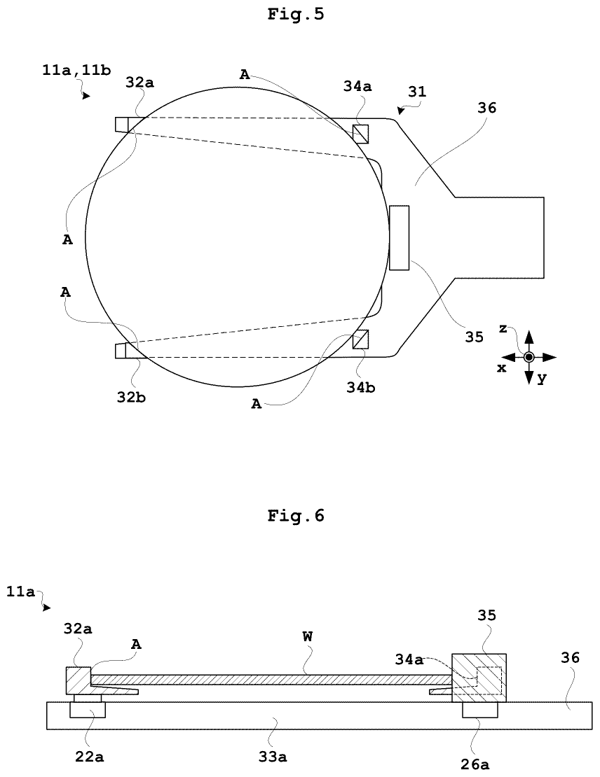

As illustrated in FIG. 5, the wall portions A of the guide member 32a, the guide member 32b, the guide member 34a, and the guide member 34b are arranged so as to belong to an imaginary circle slightly larger than the substrate W. As a result, the substrate W can be accommodated in a receiving region of the substrate W constituted by the thin portions of the guide member 32a, the guide member 32b, the guide member 34a, and the guide member 34b.

The pusher 35 is provided at the distal end portion of the connecting portion 36, and can push the substrate W held by the guide member 32a, the guide member 32b, the guide member 34a, and the guide member 34b in the front direction. The pusher 35 can move backward to be in the open state, and can move forward to be in the closed state. In order for the first blade 33a and the second blade 33b to grip the substrate W, first, the substrate W is held by the guide member 32a, the guide member 32b, the guide member 34a, and the guide member 34b with the pusher 35 in the open state (see FIG. 5). The substrate W is sandwiched between the guide member 32a and the guide member 32b, and the pusher 35 with the pusher 35 in the closed state. FIG. 6 is a cross-sectional view illustrating this state. In this manner, the substrate W is caught and held. The pusher 35 is provided on the upper surface of the base member 31, and is displaceable between a retracted state where the pusher is retracted from the outer peripheral surface of the substrate and a contact state where the pusher is in contact with the outer peripheral surface of the substrate.

### 3. Sensor

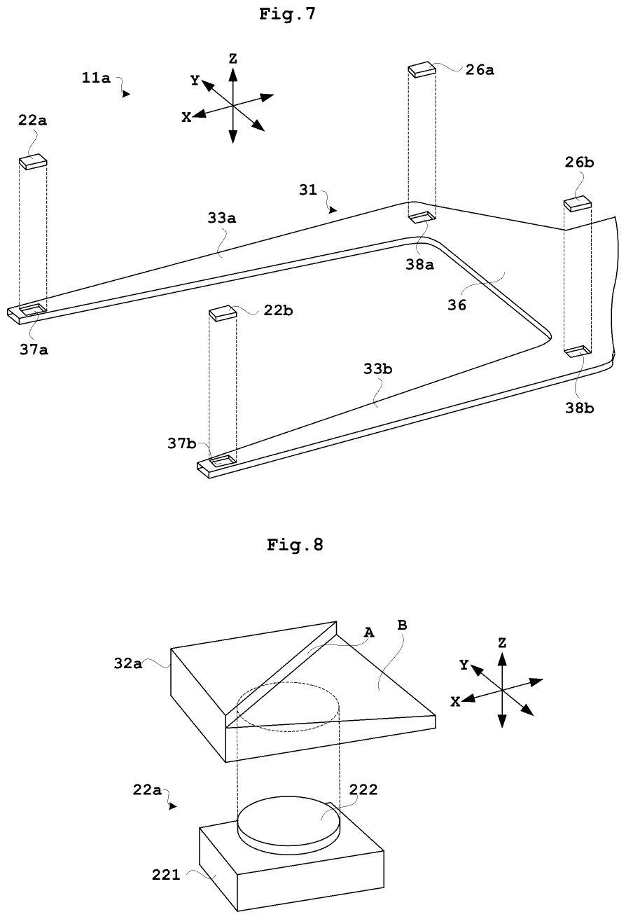

FIG. 7 is an exploded perspective view illustrating the configuration of the taking hand 11a. In FIG. 7, since the guide member 32a, the guide member 32b, the guide member 34a, and the guide member 34b are omitted, it is easy to understand how the sensor 22a, the sensor 22b, the sensor 26a, and the sensor 26b are assembled in the taking hand 11a. That is, a first recess 37a for embedding the sensor 22a is provided at the distal end of the first blade 33a. Similarly, a second recess 38a for embedding the sensor 26a is provided at the proximal end of the first blade 33a. In addition, a recess 37b for embedding the sensor 22b is provided at the distal end portion of the second blade 33b. Similarly, a recess 38b for embedding the sensor 26b is provided at the proximal end portion of the second blade 33b. As described above, the base member 31 has the plurality of recesses in which each of the sensors is embedded. The sensor 22a corresponds to the first sensor of the present invention. The sensor 22b corresponds to the second sensor of the present invention.

FIG. 8 is an exploded perspective view illustrating a positional relationship between the sensor 22a and the guide member 32a. The guide member 32a and the sensor 22a are arranged in the Z direction. The sensor 22a includes a main body 221 and an elastomer 222 including an elastic member. When the sensor 22a is attached to the first blade 33a, the main body 221 is embedded in the first recess 37a, so that the elastomer 222 protrudes from the upper surface of the first blade 33a. The guide member 32a is fixed to the elastomer 222. Therefore, the sensor 22a is provided between the base member 31 and the guide member 32a. When the substrate W is placed on the guide member 32a, the elastomer 222 is deformed. Based on this, the sensor 22a senses whether or not the substrate W has come into contact with the guide member 32a. That is, the sensor 22a is configured to sense the substrate W coming into contact with the guide member 32a.

More specifically, the sensor 22a is a tactile sensor that can detect a load input to the guide member 32a. Therefore, the sensor 22a outputs a signal indicating 0 mg in a case where the substrate W is not placed on the guide member 32a, and outputs a signal indicating the weight of the substrate in a case where the substrate W is placed on the guide member 32a. Particularly, since the substrate W is supported by the guide member 32a, the guide member 32b, the guide member 34a, and the guide member 34b, the weight of the substrate W is dispersed to each guide member. Therefore, the sensor 22a outputs only a signal indicating a weight smaller than the total weight of the substrate W at the maximum.

The sensor 26a also has the same configuration as that of the sensor 22a. That is, the sensor 26a is configured to sense the substrate W coming into contact with the guide member 34a. In this manner, the sensor 22a and the sensor 26a individually sense the substrate W coming into contact with the corresponding guide.

The sensor 26a can detect a load input to the guide member 34a. This point is the same as the configuration of the sensor 22a.

The sensor 22b and the sensor 26b also have the same configurations as those of the sensor 22a and the sensor 26a. The sensor 22b senses whether or not the substrate W has come into contact with the guide member 32b. The sensor 26b senses whether or not the substrate W has come into contact with the guide member 34b. Each of the sensors is a tactile sensor and is provided between the base member 31 and each of the guides.

The sensor 22b can detect a load input to the guide member 32b. Similarly, the sensor 26a can detect a load input to the guide member 34a. Similarly, the sensor 26b can detect a load input to the guide member 34b. This point is the same as the configuration of the sensor 22a.

As will be described later, the sensor 22a, the sensor 22b, the sensor 26a, and the sensor 26b detect the timing at which the substrate W comes into contact with the guide. Therefore, each of the sensors only needs to be able to sense whether or not the substrate W has come into contact with each corresponding guide member, and does not necessarily need to have a function of detecting a load input to each guide member.

### 4. Method for Detecting Temporal Change of Hand Using Sensor

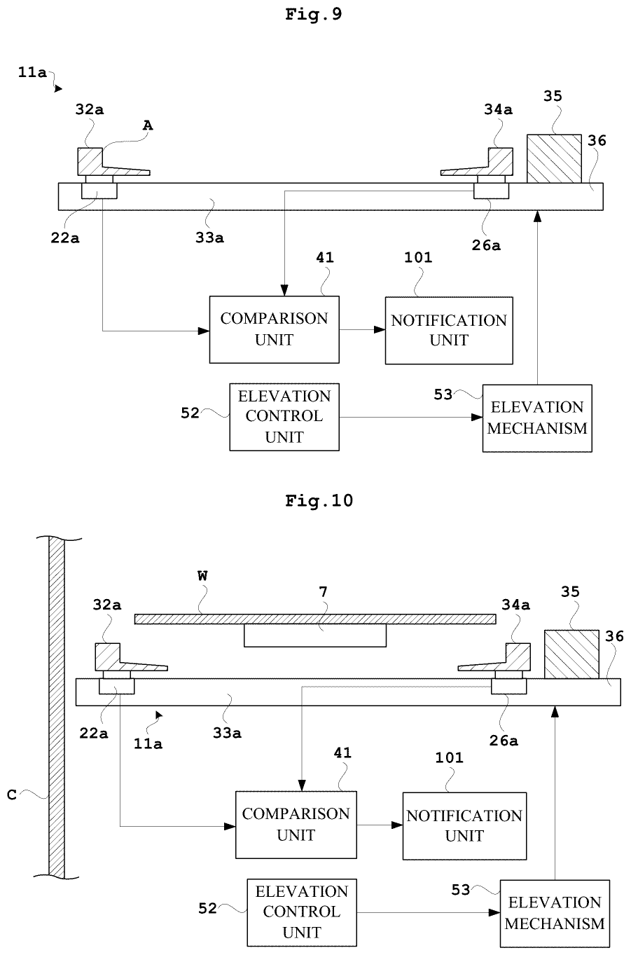

Hereinafter, an inspection method for the taking hand 11a using the sensor 22a and the sensor 26a will be described with reference to FIGS. 9 to 14. According to the inspection method, the temporal change of the taking hand 11a can be detected. Specifically, the inspection method is to detect the drooping of the taking hand 11a. The indexer robot IR having the taking hand 11a is configured by fastening a plurality of rigid members with screws or the like. When the indexer robot IR is used for a long period of time, a phenomenon occurs in which a screw or the like for fastening is loosened and the distal end of the taking hand 11a is drooped. When this phenomenon is left, malfunction of the indexer robot IR occurs. According to the configuration of the present embodiment, it is possible to quickly find the dropping of the taking hand 11a while the dropping is slight, and to encourage necessary maintenance.

The drooping of the returning hand 11b can be analogized from the state of the taking hand 11a. In this regard, in the case of requiring strict accuracy, the sensor 22a and the sensor 26a may be provided in the returning hand 11b. In this way, the drooping of the returning hand 11b can be found according to the same principle as the following description. That is, the returning hand 11b can perform each operation described with reference to FIGS. 9 to 14 on the substrate W placed on the path 24.

Each configuration related to the inspection will be described with reference to FIG. 9. First, a comparison unit 41 will be described. The comparison unit 41 corresponds to the determination unit of the present invention. The comparison unit 41 is configured to determine an inclination state of the taking hand 11a with respect to the substrate W based on a time difference between a timing at which the sensor 22a senses the substrate W and a timing at which the sensor 26a senses the substrate. More generally, the comparison unit 41 determines an inclination state of the hand with respect to the substrate W based on a time difference between timings at which each of the sensors individually senses the substrate W. Specifically, the comparison unit 41 can determine whether or not the distal end portion of the base member 31 is displaced downward with respect to the proximal end portion. When the substrate W is not placed, the sensor 22a and the sensor 26a do not sense the substrate W. At this time, the comparison unit 41 does not operate. The notification unit 101 does not issue a notification based on the fact that a signal related to the notification is not output by the comparison unit 41.

The notification unit 101 is configured to notify that the taking hand 11a is drooped. A specific notification method of the notification unit 101 is not particularly limited, but may be issuing notification by sound or light emission, transmitting a warning signal to a host computer of the plant, or the like. The notification unit 101 issues a warning about the drooping of the taking hand 11a by notifying that the index value indicating a difference in sensing timing is larger than a predetermined value.

An elevation mechanism 53 is configured to move the taking hand 11a upward in the Z direction. An elevation control unit 52 is configured to control the elevation mechanism 53.

FIG. 10 illustrates a case where the drooping of the taking hand 11a is detected using the substrate W stored in the carrier C. The substrate W used at this time may have a flat shape, and may be a wafer for inspection. In this case, the taking hand 11a is inspected when the substrate processing is stopped. The drooping of the taking hand 11a may be detected using the substrate W to be actually subjected to the substrate processing. In this case, it is possible to constantly monitor the necessity of maintenance of the taking hand 11a while performing the operation related to the substrate processing.

FIG. 10 illustrates a state when the taking hand 11a is located below the substrate W supported by the comb-shaped member 7 of the carrier C. At this time, both of the guide member 32a and the guide member 34a are separated from the substrate W. Since neither the sensor 22a nor the sensor 26a detects the substrate W, the determination operation of the comparison unit 41 and the notification operation of the notification unit 101 are not executed.

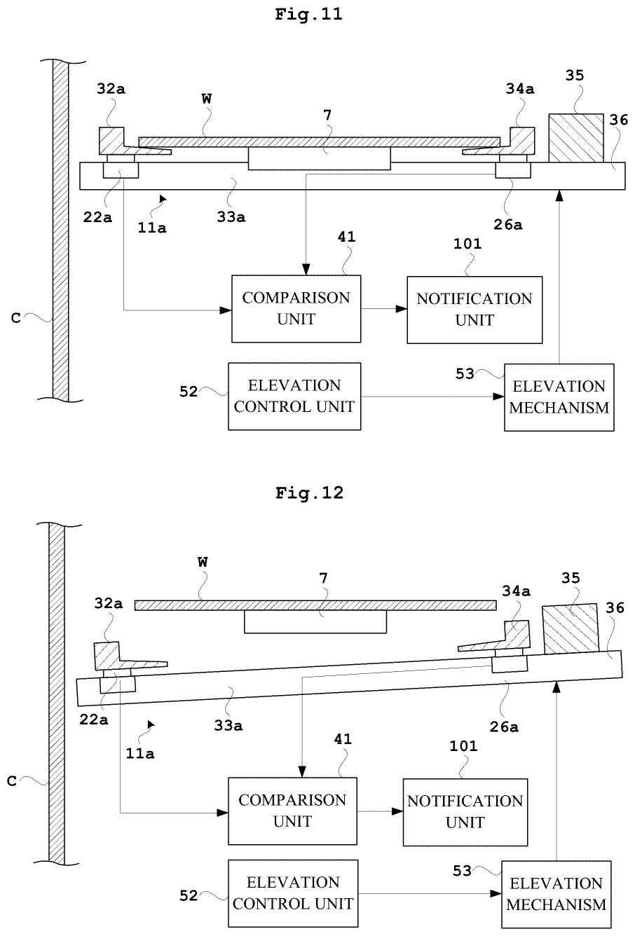

FIG. 11 illustrates a state where the elevation mechanism 53 operates from the state of FIG. 10 and the taking hand 11a acquires the substrate W. The elevation control unit 52 is configured to move the taking hand 11a located at a lower portion of the substrate W in a stationary state in the carrier C upward to bring the substrate W into contact with the plurality of guides (the guide member 32a and the guide member 34a).

In the case of FIG. 11, since the taking hand 11a is kept horizontal and is not drooped, the guide member 32a and the guide member 34a come into contact with the substrate W almost simultaneously. Thus, the sensor 22a and the sensor 26a sense the substrate W at substantially the same timing.

The sensor 22a sends a detection signal to the comparison unit 41 at a timing when the substrate W is sensed. The comparison unit 41 recognizes the detection time of the substrate W by inputting the detection signal. The detection time at this time is referred to as a first time t1. Similarly, the sensor 26a sends a detection signal to the comparison unit 41 at a timing when the substrate W is sensed. The comparison unit 41 recognizes the detection time of the substrate W by inputting the detection signal. The detection time at this time is referred to as a second time t2.

The comparison unit 41 calculates a difference between the first time t1 and the second time t2 and determines whether or not the difference falls within a predetermined range defined by a predetermined value. Specifically, the comparison unit 41 subtracts the second time t2 from the first time t1, and calculates an index value which is an absolute value of the result. The comparison unit 41 then compares the index value with the predetermined value, and when the index value is larger than the predetermined value, sends a signal instructing the notification unit 101 to notify. When the index value is equal to or less than the predetermined value, the comparison unit 41 does not send a signal instructing the notification unit 101. The predetermined value is determined based on the index value when the taking hand 11a is drooped and a difference between the first time t1 and the second time t2 occurs. Therefore, when the index value is larger than the predetermined value, it can be determined that the drooping of the taking hand 11a has progressed to such an extent that maintenance is required. When the index value is equal to or less than the predetermined value, it can be determined that the drooping of the taking hand 11a is within an allowable range.

Particularly, in the case of FIG. 11, since the taking hand 11a is not drooped, the comparison unit 41 does not send a signal instructing the notification unit 101 to notify. That is, in the case of FIG. 11, the comparison unit 41 determines that the index value is equal to or less than the predetermined value. As a result, the notification unit 101 does not issue a notification regarding the drooping of the taking hand 11a.

FIG. 12 illustrates a case where the taking hand 11a is drooped. That is, FIG. 12 illustrates a state where the drooped taking hand 11a is located below the substrate W supported by the comb-shaped member 7 of the carrier C. At this time, both of the guide member 32a and the guide member 34a are separated from the substrate W. Since neither the sensor 22a nor the sensor 26a detects the substrate W, the determination operation of the comparison unit 41 and the notification operation of the notification unit 101 are not executed.

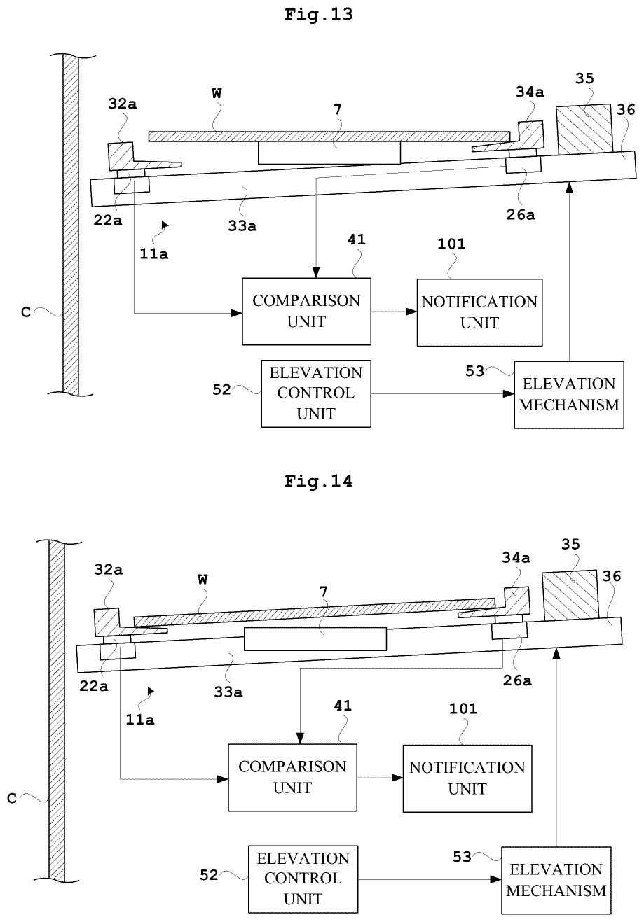

FIG. 13 illustrates a state where the elevation mechanism 53 operates from the state of FIG. 12 and the taking hand 11a acquires the substrate W. The elevation control unit 52 is caused to move the taking hand 11a located at the lower portion of the substrate W in a stationary state in the carrier C upward to bring the substrate W into contact with the guide member 32a and the guide member 34a.

In the case of FIG. 13, since the taking hand 11a is inclined and drooped, the guide member 34a comes into contact with the substrate W earlier than the guide member 32a. Thus, the sensor 26a senses the substrate W at a timing earlier than that of the sensor 22a.

When the elevation mechanism 53 further moves the taking hand 11a upward, as illustrated in FIG. 14, the guide member 32a comes into contact with the substrate W behind the guide member 34a. Thus, the sensor 22a senses the substrate at a timing later than that of the sensor 26a.

The comparison unit 41 calculates a difference between the first time t1 and the second time t2 and determines whether or not the difference falls within a predetermined range defined by a predetermined value. In the cases of FIGS. 12 to 14, since the taking hand 11a is drooped, the comparison unit 41 sends a signal instructing the notification unit 101 to notify. That is, in the case of FIG. 14, the comparison unit 41 determines that the index value is larger than the predetermined value. As a result, the notification unit 101 issues a notification regarding the drooping of the taking hand 11a.

### 5. Other Configurations

As illustrated in FIG. 1, the indexer block 3 includes the control unit 100 related to control of the indexer robot IR. The control unit 100 is configured as, for example, a central processing unit (CPU). The specific configuration of the control unit 100 is not limited, and for example, the control related to the comparison unit 41 and the taking hand 11a and the control related to the returning hand 11b may be configured by a single processor or may be configured by individual processors.

Examples of the control related to the control unit 100 include control related to forward and backward movement of the taking hand 11a, forward and backward movement of the returning hand 11b, rotation of the taking hand 11a, rotation of the returning hand 11b, elevation of the taking hand 11a, elevation of the returning hand 11b, and control of the pusher.

A storage unit stores a program related to control and a parameter such as a predetermined value. The storage unit may be configured as a single device or may be configured as individual devices corresponding to each control. The indexer block 3 of the present invention has no particular limitation on the configuration of the device that implements the storage unit.

### 6. Flowchart of Inspection Method

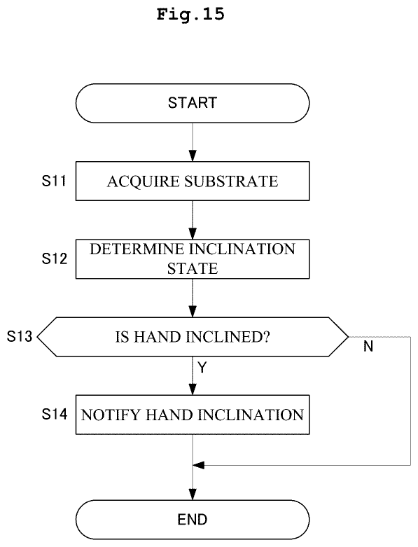

Hereinafter, an actual inspection method for the substrate transport apparatus will be described with reference to a flowchart illustrated in FIG. 15.

Step S11: The taking hand 11a is caused to acquire the substrate W stored in the carrier C.

Step S12: The comparison unit 41 determines an inclination state of the taking hand 11a with respect to the substrate W based on a difference between a timing at which the sensor 22a senses the substrate W and a timing at which the sensor 26a senses the substrate.

Step S13: In a case where it is determined that the taking hand 11a is inclined, the processing proceeds to step S14, and otherwise, the processing ends.

Step S14: The comparison unit 41 sends a signal instructing the notification to the notification unit 101, and the notification unit 101 receives the signal and executes predetermined notification. As a result, the processing ends.

### 7. Effects of Present Invention

According to the above configuration, the taking hand 11a including the guide member 32a provided on the upper surface of the base member 31 and with which the peripheral edge of the substrate W comes into contact, the sensor 22a sensing the substrate W coming into contact with the guide member 32a, the guide member 34a provided on the upper surface of the base member 31 and with which the peripheral edge of the substrate W comes into contact, and the sensor 26a sensing the substrate W coming into contact with the guide member 34a; and the comparison unit 41 determining an inclination state of the taking hand 11a with respect to the substrate W based on a time difference between a timing at which the sensor 22a senses the substrate W and a timing at which the sensor 26a senses the substrate W are provided. With such a configuration, it is possible to provide the indexer block 3 capable of continuously detecting a temporal change of the taking hand 11a. There is a predetermined relationship between a timing at which the sensor 22a senses the substrate W and a timing at which the sensor 26a senses the substrate W. When the predetermined relationship collapses while the timing is measured for each of the substrates W held by the taking hand 11a, it can be determined that the positional deviation of the taking hand 11a with respect to the substrate W has occurred. Therefore, according to the present invention, it is possible to provide the indexer block 3 that automatically perceives a time required for maintenance and facilitates maintenance.

According to the above configuration, the guide member 32a is provided at the distal end portion of the base member 31, and the guide member 34a is provided at the proximal end portion of the base member 31. The guide member 32a includes the sensor 22a sensing the substrate W, and the guide member 34a includes the sensor 26a sensing the substrate W. The comparison unit 41 determines an inclination state of the taking hand 11a in the front-rear direction P based on a time difference between a timing at which the sensor 22a senses the substrate W and a timing at which the sensor 26a senses the substrate W. The comparison unit 41 determines whether or not the distal end portion of the base member 31 is displaced downward with respect to the proximal end portion. When the indexer block 3 is operated, a temporal change of the taking hand 11a in which the distal end portion is displaced downward with respect to the proximal end portion may occur. According to the above configuration, since the guide member 32a is provided at the distal end portion of the base member 31 and the guide member 34a is provided at the proximal end portion of the base member 31, such a temporal change can be easily sensed.

According to the above configuration, the notification unit 101 notifies that the index value indicating the time difference in substrate detection timing by the sensor is larger than the predetermined value. This facilitates maintenance of the indexer block 3.

According to the above configuration, the elevation mechanism 53 vertically moving the taking hand 11a and the elevation control unit 52 controlling the elevation mechanism 53 are provided. The elevation control unit 52 is caused to move the taking hand 11a located at the lower portion of the substrate W in a stationary state upward to bring the substrate W into contact with the plurality of guides (the guide member 32a and the guide member 34a). With such a configuration, the substrate W can be brought into contact with the guide member 32a and the guide member 34a at the same time. Therefore, according to the above configuration, the object of the present invention can be more easily realized.

According to the above configuration, each of the sensors (the sensor 22a, the sensor 22b, the sensor 26a, and the sensor 26b) is a tactile sensor, and is provided between the base member 31 and each of the guides (the guide member 32a, the guide member 32b, the guide member 34a, and the guide member 34b). With such a configuration, each sensor can more directly and reliably detect the substrate W placed on the base member 31.

According to the above configuration, each of the guides (the guide member 32a, the guide member 32b, the guide member 34a, and the guide member 34b) includes the support portion (tapered portion B) that brings the lower portion of the substrate W into contact therewith, and the wall portion A that brings the outer peripheral surface of the substrate W into contact therewith. With such a configuration, a contact portion between the substrate W and the guide is reduced as much as possible. When the outer peripheral surface of the substrate W comes into contact with the wall portion A, positional displacement of the substrate W caused when the substrate W is gripped is appropriately prohibited. Therefore, according to the above configuration, it is possible to provide the indexer block 3 suitable for transporting the substrate W.

According to the above configuration, the base member 31 includes the plurality of recesses in which each of the sensors (the sensor 22a, the sensor 22b, the sensor 26a, and the sensor 26b) is embedded. With such a configuration, the thickness of the taking hand 11a in the height direction can be suppressed, so that it is possible to provide the indexer block 3 in which the taking hand 11a does not collide with the substrate W during substrate transport.

According to the above configuration, each of the sensors (the sensor 22a, the sensor 22b, the sensor 26a, and the sensor 26b) only needs to sense whether or not the substrate W has come into contact with the corresponding guide (the guide member 32a, the guide member 32b, the guide member 34a, and the guide member 34b). With such a configuration, the present invention can be realized by a relatively inexpensive sensor.

According to the above configuration, a carrier placement shelf capable of placing a carrier C on which substrates W in a horizontal posture are stacked in a vertical direction and stored thereon is provided. Therefore, according to the above configuration, the temporal change of the taking hand 11a can be detected with reference to the carrier C.

According to the above configuration, a single-substrate-type processing unit performing predetermined processing on substrates W transported by the indexer block 3 one by one is provided. According to the above configuration, it is possible to provide a substrate processing apparatus that facilitates maintenance and can perform desired substrate processing.

According to the above configuration, an acquisition process of causing the taking hand 11a to acquire the flat substrate W, and a determination process of determining an inclination state of the taking hand 11a with respect to the substrate W based on a time difference between timings at which each of the sensors (the sensor 22a and the sensor 26a) individually senses the substrate W are provided. With such a configuration, it is possible to provide an inspection method capable of reliably inspecting an inclination state of the taking hand 11a.

### 8. Modifications

The present invention is not limited to the above-described configuration, and modifications can be made as follows.

### Modification 1

In the above-described embodiment, the sensor 22a is provided at the distal end portion of the base member 31, and the sensor 26a is provided at the proximal end portion of the base member 31, but the present invention is not limited to this configuration. The sensor 26a may be provided at the distal end portion of the base member 31. In this case, the guide member 32a is provided at one end of the base member 31, and the guide member 34a is provided at the other end of the distal end portion of the base member 31. In the modification, it is not always necessary to provide a sensor at the proximal end portion of the base member 31.

Specifically, Modification 1 has a configuration in which the guide member 32a is provided at the distal end portion of the first blade 33a, and the guide member 34a is provided at the distal end portion of the second blade 33b. The comparison unit 41 of the present modification operates similarly to the above-described embodiment based on the outputs of the sensor 22a provided in the guide member 32a and the sensor 26a provided in the guide member 34a. That is, the comparison unit 41 determines whether or not the guide member 32a is displaced in the vertical direction with respect to the guide member 34a, that is, whether or not the base member 31 is inclined in the right-left direction Q, based on the detection results of the sensor 22a and the sensor 26a.

According to the above configuration, the guide member 32a is provided on one end side in the right-left direction Q of the distal end portion of the base member 31, the guide member 34a is provided on the other end side in the right-left direction Q of the distal end portion of the base member 31, and the comparison unit 41 determines an inclination state of the taking hand 11a in the right-left direction Q based on a time difference between a timing at which the sensor 22a senses the substrate W and a timing at which the sensor 26a senses the substrate W. It is determined whether or not the guide member 32a is displaced in the vertical direction with respect to the guide member 34a. When the indexer block 3 is operated, a temporal change of the taking hand 11a in which one of the distal end portions is displaced downward with respect to the other of the distal end portions may occur. According to the above configuration, since the guide member 32a is provided at one end of the distal end portion of the base member 31, and the guide member 34a is provided at the other end of the distal end portion of the base member 31, such a temporal change can be easily sensed.

### Modification 2

Even when the guide member 32a is provided at one end of the proximal end portion of the base member 31, and the guide member 34a is provided at the other end of the proximal end portion of the base member 31, the same effect as that of Modification 1 can be obtained.

### Modification 3

As a further modification of Modification 1, it is also possible to employ a configuration in which the drooping of the taking hand 11a and the inclination of the taking hand 11a in the right-left direction Q with respect to the base member 31 are simultaneously detected using three sensors. Examples can be referred to for the operation of the comparison unit 41 related to the drooping of the taking hand 11a. Regarding the operation of the comparison unit 41 related to the inclination of the taking hand 11a in the right-left direction Q, Modification 1 can be referred to.

The taking hand 11a of the present modification has the guide member 32a and the sensor 22a at the distal end portion of the first blade 33a, and has the guide member 34a and the sensor 26a at the proximal end portion of the first blade 33a. The taking hand 11a of the present modification includes the guide member 32b and the sensor 22b at the distal end portion of the second blade 33b. FIGS. 5 and 7 can be referred to for understanding the respective positional relationships. The guide member 32a corresponds to the first guide of the present modification, and the sensor 22a corresponds to the first sensor of the present invention. The guide member 34a corresponds to the third guide of the present modification, and the sensor 26a corresponds to the third sensor of the present invention. The guide member 32b corresponds to the second guide of the present modification, and the sensor 22b corresponds to the second sensor of the present invention.

The taking hand 11a of the present modification includes the guide member 34a provided at the proximal end portion of the base member 31 and with which the peripheral edge of the substrate comes into contact, and the sensor 26a detecting the substrate W coming into contact with the guide member 34a. The comparison unit 41 of the present modification determines an inclination state of the taking hand 11a in the front-rear direction P based on a time difference between a timing at which the sensor 22a detects the substrate W and a timing at which the sensor 26a detects the substrate W. In particular, the comparison unit 41 can determine whether or not the distal end portion of the base member 31 is displaced downward with respect to the proximal end portion. The comparison unit 41 of the present modification determines an inclination state of the taking hand 11a in the right-left direction Q based on a time difference between a timing at which the sensor 22a detects the substrate W and a timing at which the sensor 26b senses the substrate W. In particular, the comparison unit 41 determines whether or not the guide member 32a is displaced in the vertical direction with respect to the guide member 32b. With such a configuration, it is possible to detect the inclination due to the temporal change of the taking hand 11a in two directions orthogonal to each other, so that maintenance of the indexer block 3 is facilitated.

### Modification 4

In Modification 3, the first guide, the second guide, and the third guide are configured as the guide member 32a, the guide member 32b, and the guide member 34a, respectively, but the arrangement of the first guide, the second guide, and the third guide can be freely changed. For example, in a configuration in which the first guide is the guide member 32a and the third guide is the guide member 34a, even when the second guide is set to the guide member 34b, the same effect as that of Modification 3 can be obtained. In a configuration in which the first guide is the guide member 32a and the second guide is the guide member 32b, even when the third guide is set to the guide member 34b, the same effect as that of Modification 3 can be obtained. In a configuration in which the third guide is the guide member 34a, even when the first guide is set to the guide member 32b and the second guide is set to the guide member 34b, the same effect as that of Modification 3 can be obtained.

### Modification 5

As a modification that operates using three or more sensors, the comparison unit 41 is configured to determine an inclination state of the taking hand 11a with respect to the substrate W based on two times most separated with time among a first time t1, a second time t2, and a third time t3. The first time t1 is a time indicating a timing at which the first sensor (for example, the sensor 26a) detects the substrate W, and the second time t2 is a time indicating a timing at which the second sensor (for example, the sensor 22a) detects the substrate W. The third time t3 is a time indicating a timing at which the third sensor (for example, the sensor 26b) detects the substrate W.

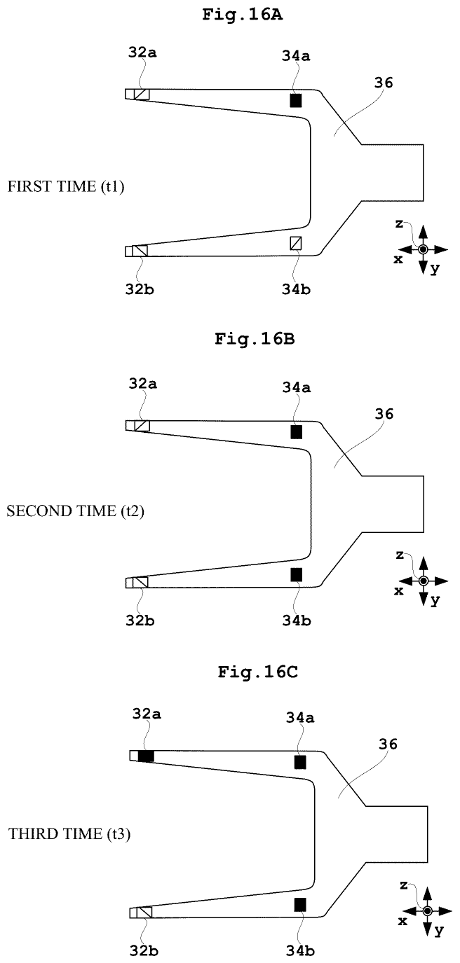

FIGS. 16A to 16C specifically illustrate the present modification. FIG. 16A is a plan view of the state of FIG. 13 in an embodiment. FIG. 16A illustrates a state when the substrate W comes into contact with the guide member 34a. The sensor 26a senses the contact of the substrate W. A time when the sensor 26a senses the substrate W is the first time t1. FIG. 16B illustrates a state when the substrate W then comes into contact with the guide member 34b. The sensor 26b senses the contact of the substrate W. A time when the sensor 26b senses the substrate W is the second time t2. FIG. 16C illustrates a state when the substrate W then comes into contact with the guide member 32a. The sensor 22a senses the contact of the substrate W. A time when the sensor 22a senses the substrate W is the third time t3.

Therefore, in this case, there are three types of index values indicating a difference in detection timing. A first index value is an index value indicating a difference between the first time t1 and the second time t2, a second index value is an index value indicating a difference between the second time t2 and the third time t3, and a third index value is an index value indicating a difference between the first time t1 and the third time t3. The comparison unit 41 determines an inclination state of the taking hand 11a with respect to the substrate W based on a time difference between two timings most separated with time among respective timings at which each of the sensors individually senses the substrate W. That is, the comparison unit 41 compares the third index value with the predetermined value to determine whether or not a signal related to the notification is sent to the notification unit 101. This is because the first time t1 and the third time t3 are most separated from each other among respective timings. With such a configuration, the temporal change of the taking hand 11a can be more sensitively sensed. Therefore, according to the above configuration, the object of the present invention can be more easily realized.

### Modification 6

In a case where it is clear that the taking hand 11a is not inclined, it is also possible to detect how much the carrier C of the load port 10 is inclined with reference to the taking hand 11a. The comparison unit 41 in this case determines an inclination state of the carrier C with respect to the taking hand 11a based on a time difference between timings at which each of the sensors individually senses the substrate W. In particular, the comparison unit 41 can determine an inclination state of the carrier C in the front-rear direction P with respect to the taking hand 11a based on a time difference between a timing at which the sensor 22a detects the substrate W and a timing at which the sensor 26a senses the substrate W.

### Modification 7

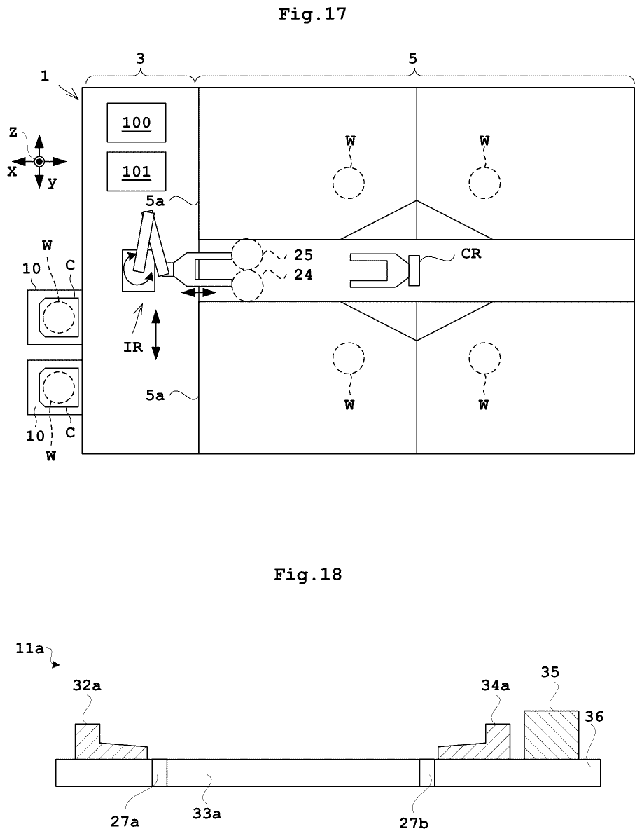

In the configuration of the embodiment, the drooping state of the taking hand 11a is determined using the substrate W stored in the carrier C, but the present invention is not limited to this configuration. As illustrated in FIG. 17, a placement portion 25 on which the substrate W having a flat shape can be placed in the vicinity of the path 24 in the processing block 5 may be provided. The placement portion 25 can place the substrate W in a horizontal posture therein, and can be accessed by the indexer robot IR The placement portion 25 may be the indexer block 3.

### Modification 8

In the above-described embodiment, the tactile sensor detects that the substrate W is placed on the guide member 32a and the guide member 34a, but the present invention is not limited to this configuration. As illustrated in FIG. 18, a distance measuring sensor 27a and a distance measuring sensor 27b may be provided on the first blade 33a. The distance measuring sensor 27a is provided at a position displaced from the guide member 32a toward the proximal end of the base member 31. The distance measuring sensor 27b is provided at a position displaced from the guide member 34b toward the distal end of the base member 31. With such a configuration, the distance measuring sensor 27a and the distance measuring sensor 27b are covered with the substrate W held by the taking hand 11a, and the sensing timing of the substrate W can be reliably detected.

### Modification 9

The present invention is not limited to the indexer block 3, and can be generally applied to a substrate transport apparatus including a robot that transports the substrate W in a horizontal posture.

What is claimed is:

1. A substrate transport apparatus having a hand capable of transporting a substrate in a horizontal posture,
wherein the hand includes
a base member,
a plurality of guides provided on an upper surface of the base member and with which a peripheral edge of a substrate comes into contact, and
a plurality of sensors configured to individually sense the substrate coming into contact with each of the guides, and
the substrate transport apparatus comprises a determination unit configured to determine an inclination state of the hand with respect to the substrate based on a time difference between timings at which each of the sensors individually senses the substrate.

2. The substrate transport apparatus according to claim 1, wherein
the hand includes
a first guide provided at a distal end portion of the base member among the guides,
a second guide provided at a proximal end portion of the base member among the guides,
a first sensor configured to sense the substrate coming into contact with the first guide among the sensors, and
a second sensor configured to sense the substrate coming into contact with the second guide among the sensors, and
in a case where a direction connecting the proximal end portion of the base member and the distal end portion of the base member is designated as a front-rear direction,
the determination unit is configured to determine an inclination state of the hand in the front-rear direction based on a time difference between a timing at which the first sensor senses the substrate and a timing at which the second sensor senses the substrate.

3. The substrate transport apparatus according to claim 1, wherein
the hand includes,
in a case where a direction connecting a proximal end portion of the base member and a distal end portion of the base member is designated as a front-rear direction, and a direction orthogonal to the front-rear direction in a horizontal plane is designated as a right-left direction,
a first guide provided on one end side in the right-left direction of the distal end portion of the base member among the guides,
a second guide provided on the other end side in the right-left direction of the distal end portion of the base member among the guides,
a first sensor configured to sense the substrate coming into contact with the first guide among the sensors, and
a second sensor configured to sense the substrate coming into contact with the second guide among the sensors, and
the determination unit is configured to determine an inclination state of the hand in the right-left direction based on a time difference between a timing at which the first sensor senses the substrate and a timing at which the second sensor senses the substrate.

4. The substrate transport apparatus according to claim 3, wherein
the hand includes
at least one third guide provided at the proximal end portion of the base member and with which the peripheral edge of the substrate comes into contact among the guides, and
a third sensor configured to sense the substrate coming into contact with the third guide among the sensors, and
the determination unit is configured
to determine an inclination state of the hand in the front-rear direction based on a time difference between a timing at which the first sensor senses the substrate and a timing at which the third sensor senses the substrate, and
to determine an inclination state of the hand in the right-left direction based on a time difference between a timing at which the first sensor senses the substrate and a timing at which the second sensor senses the substrate.

5. The substrate transport apparatus according to claim 1, further comprising a notification unit configured to notify that an index value indicating the time difference is larger than a predetermined value.

6. The substrate transport apparatus according to claim 1, further comprising:
an elevation mechanism configured to vertically move the hand; and
an elevation control unit configured to control the elevation mechanism,
wherein the elevation control unit is configured to move the hand located at a lower portion of the substrate in a stationary state upward to bring the substrate into contact with the plurality of guides.

7. The substrate transport apparatus according to claim 1, wherein the determination unit is configured to determine an inclination state of the hand with respect to the substrate based on a time difference between two timings most separated with time among respective timings at which each of the sensors individually senses the substrate.

8. The substrate transport apparatus according to claim 1, wherein each of the sensors is a tactile sensor and is provided between the base member and each of the guides.

9. The substrate transport apparatus according to claim 1, wherein each of the guides includes a support portion bringing a lower portion of the substrate into contact with each of the guides, and a wall portion bringing an outer peripheral surface of the substrate into contact with each of the guides.

10. The substrate transport apparatus according to claim 1, wherein the base member includes a plurality of recesses in which each of the sensors is embedded.

11. The substrate transport apparatus according to claim 1, wherein each of the sensors is configured to sense whether or not the substrate comes into contact with each corresponding guide.

12. A substrate processing apparatus comprising:
the substrate transport apparatus according to claim 1; and
a carrier placement shelf capable of placing a carrier on which substrates in a horizontal posture are stacked in a vertical direction and stored on the carrier placement shelf,
wherein loading and unloading of the substrate into and from the carrier are performed by the substrate transport apparatus.

13. The substrate processing apparatus according to claim 12, wherein the determination unit is configured to determine an inclination state of the carrier with respect to the hand based on a time difference between timings at which each of the sensors individually senses the substrate.

14. The substrate processing apparatus according to claim 12, further comprising a single-substrate-type processing unit configured to process substrates transported by the substrate transport apparatus one by one.

15. An inspection method for a substrate transport apparatus having a hand including a base member, a plurality of guides provided on an upper surface of the base member and with which a peripheral edge of a substrate comes into contact respectively, and a plurality of sensors configured to individually sense the substrate coming into contact with each of the guides, the inspection method comprising:
causing the hand to acquire the substrate; and
determining an inclination state of the hand with respect to the substrate based on a time difference between timings at which each of the sensors individually senses the substrate.
